(19) United States
(12) Patent Application Publication
(10) Pub. No.: US 2026/0334025 A1
(43) Pub. Date: Oct. 22, 2026

(54) DISPLAY APPARATUS AND DISPLAY PANEL

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Zuoji NIU, Beijing (CN); Tinghua SHANG, Beijing (CN); Biao LIU, Beijing (CN); Jiaxing CHEN, Beijing (CN); Yixuan LONG, Beijing (CN); Qian XU, Beijing (CN); Yan HUANG, Beijing (CN); Yuge CHU, Beijing (CN); Yi ZHANG, Beijing (CN)

(21) Appl. No.: 19/483,667

(22) PCT Filed: Apr. 29, 2024
(86) PCT No.: PCT/CN2024/090577

§ 371 Date: Nov. 12, 2025

(30) Foreign Application Priority Data
May 25, 2023 (CN) 202310601944.3

(51) Int. Cl. H10K 59/131; H10K 59/80

(52) U.S. Cl. CPC H10K 59/131; H10K 59/80515

(57) ABSTRACT

A display panel includes: a substrate; and a conductive layer on a side of the substrate and including a plurality of power supply lines. The plurality of subpixels include first, second and third subpixels emitting different colors of light. The anodes of the first, second and third subpixels are first, second and third anodes, respectively, and the first and third anodes each have an area greater than the second anode. An overlapping region is present between each of orthographic projections of the first, second and third anodes on the substrate and an orthographic projection of a corresponding power supply line on the substrate, and an area of the overlapping region between at least one of the first anode, the second anode or the third anode and the power supply lines is less than ½ an area of a corresponding anode.

### TECHNICAL FIELD

The present disclosure relates to the field of display technology, and particularly relates to a display apparatus and a display panel.

### BACKGROUND

With the development of economy, display panels are more and more widely used in people's lives. However, the display effect of the conventional display panel is poor.

### SUMMARY

An object of the present disclosure is to provide a display apparatus and a display panel which can improve the display effect.

According to one aspect of the present disclosure, there is provided a display panel, including a plurality of subpixels, and a plurality of pixel driving circuits for driving the plurality of subpixels respectively to emit light; each pixel driving circuit includes a drive transistor, a data writing transistor, and a first emission control transistor, wherein a first electrode of the data writing transistor is connected to a data line, a second electrode of the data writing transistor is connected to a first electrode of the drive transistor, a first electrode of the first emission control transistor is connected to a power supply line, and a second electrode of the first emission control transistor is connected to the first electrode of the drive transistor; and the display panel further includes:
a substrate; and
a conductive layer on a side of the substrate and including a plurality of power supply lines; and
each subpixel includes an anode and a cathode opposite to each other, the anode is on a side of the conductive layer away from the substrate, and the cathode is on a side of the anode away from the substrate; the plurality of subpixels include a first subpixel, a second subpixel and a third subpixel having different emission colors; the anode of the first subpixel is a first anode, the anode of the second subpixel is a second anode, the anode of the third subpixel is a third anode, and the first anode and the third anode each have an area greater than the second anode; and an overlapping region is present between each of orthographic projections of the first anode, the second anode and the third anode on the substrate and an orthographic projection of a corresponding power supply line on the substrate, and an area of the overlapping region between at least one of the first anode, the second anode or the third anode and the power supply line is less than ½ an area of a corresponding anode.

Further, a ratio of an area of the overlapping region between the orthographic projections of the first anode and the power supply line to an area of the first anode is less than a ratio of an area of the overlapping region between the orthographic projections of the second anode and the power supply line to an area of the second anode; and/or, a ratio of an area of the overlapping region between the orthographic projections of the third anode and the power supply line to an area of the third anode is less than a ratio of an area of the overlapping region between the orthographic projections of the second anode and the power supply line to the area of the second anode.

Further, the first subpixel is a red subpixel, the second subpixel is a green subpixel, and the third subpixel is a blue subpixel.

Further, the conductive layer includes a plurality of data lines, and an orthographic projection of a corresponding data line on the substrate is spaced apart from the orthographic projection of the second anode on the substrate; and an overlapping region is present between the orthographic projection of the corresponding data line on the substrate and each of the orthographic projections of the first anode and the third anode on the substrate.

Further, the plurality of subpixels form a plurality of pixels, one pixel includes multiple subpixels, and the plurality of pixels form a plurality of pixel rows and a plurality of pixel columns; each data line extends in a pixel column direction, and the plurality of data lines are arranged in a pixel row direction; and the second anode is located between two adjacent data lines; and
in the pixel column direction, at least some first anodes and at least some third anodes are alternated, and an overlapping region is present between each of orthographic projections of the alternated first anodes and third anodes on the substrate and the orthographic projection of the corresponding data line on the substrate.

Further, the plurality of the data lines form a plurality of first line groups arranged at intervals in the pixel row direction, wherein one first line group includes at least two data lines, and the second anode is located between two adjacent first line groups; and
an overlapping region is present between each of the orthographic projections of the alternated first anodes and third anodes on the substrate and each of orthographic projections of the at least two data lines in the first line group on the substrate.

Further, one power supply line includes a plurality of conductive blocks distributed in the pixel column direction, wherein two adjacent conductive blocks are connected via a conductive line;
an overlapping region is present between the orthographic projection of the second anode on the substrate and an orthographic projection of a corresponding conductive block on the substrate, and an area of the overlapping region is less than an area of the orthographic projection of the conductive block on the substrate; and
for two adjacent conductive lines in the pixel column direction, an overlapping region is present between an orthographic projection of one conductive line on the substrate and the orthographic projection of the first anode on the substrate, while an overlapping region is present between an orthographic projection of the other conductive line on the substrate and the orthographic projection of the third anode on the substrate.

Further, an area of a region of the orthographic projection of the conductive block on the substrate not overlapped with the orthographic projection of the second anode on the substrate is greater than ⅕ the area of the orthographic projection of the conductive block on the substrate.

Further, an area of a region of the orthographic projection of the conductive block on the substrate not overlapped with the orthographic projection of the second anode on the substrate is greater than ⅕ an area of the orthographic projection of the second anode on the substrate.

Further, the plurality of the power supply lines form a plurality of second line groups arranged at intervals in the pixel row direction, wherein one second line group includes two power supply lines spaced apart; the plurality of second line groups and the plurality of first line groups are alternated in the pixel row direction; and
for the two power supply lines in one second line group, the plurality of conductive blocks in one power supply line correspond to the plurality of conductive blocks in the other power supply line, respectively, and orthographic projections of one conductive block in the one power supply line and the corresponding conductive block in the other power supply line on the substrate are overlapped with the orthographic projection of a same second anode on the substrate.

Further, each conductive block is provided with a hollowed-out portion, and an orthographic projection of the hollowed-out portion on the substrate is within the orthographic projection of the second anode on the substrate.

Further, the plurality of subpixels form a plurality of pixels, one pixel includes multiple subpixels, and the plurality of pixels form a plurality of pixel rows and a plurality of pixel columns; each power supply line extends in a pixel column direction, and the plurality of power supply lines are arranged in a pixel row direction; and one power supply line includes a plurality of conductive blocks distributed in the pixel column direction, wherein two adjacent conductive blocks are connected via a conductive line, and each conductive block is provided with a hollowed-out portion; and
an overlapping region is present between the orthographic projection of the first anode on the substrate and an orthographic projection of a corresponding conductive block on the substrate, and an orthographic projection of the hollowed-out portion on the substrate is within the orthographic projection of the first anode on the substrate; and/or, an overlapping region is present between the orthographic projection of the third anode on the substrate and an orthographic projection of the corresponding conductive block on the substrate, and an orthographic projection of the hollowed-out portion on the substrate is within the orthographic projection of the third anode on the substrate.

Further, the conductive layer includes a plurality of data lines, and an orthographic projection of a corresponding data line on the substrate is spaced apart from the orthographic projections of the first anode and the third anode on the substrate; and an overlapping region is present between the orthographic projection of the corresponding data line on the substrate and the orthographic projection of the second anode on the substrate;
each data line extends in a pixel column direction, and the plurality of data lines are arranged in a pixel row direction; and the first anode and the third anode are located between two adjacent data lines;
a plurality of second anodes form a plurality of first electrode columns, and one first electrode column includes a plurality of second anodes distributed in the pixel column direction; and an overlapping region is present between each of orthographic projections of a plurality of second anodes in the first electrode column on the substrate and an orthographic projection of a same data line on the substrate.

Further, the conductive layer further includes a first anode transition part and a second anode transition part; wherein in a pixel row direction, two adjacent second anodes are connected to the first anode transition part and the second anode transition part, respectively; and a plurality of pixel circuits include a first pixel circuit and a second pixel circuit which correspond to the two adjacent second anodes, respectively, wherein the first pixel circuit is connected to a corresponding second anode through the first anode transition part, and the second pixel circuit is connected to a corresponding second anode through the second anode transition part;
an orthographic projection of the first anode transition part on the substrate is overlapped with an orthographic projection of the second electrode of the drive transistor in the first pixel circuit on the substrate; and
an orthographic projection of the second electrode of the drive transistor in a pixel circuit adjacent to the second pixel circuit on the substrate is overlapped with an orthographic projection of the second anode transition part on the substrate.

Further, each power supply line includes a plurality of conductive blocks, two adjacent conductive blocks are connected via a conductive line, and each conductive block is provided with a hollowed-out portion; and
an orthographic projection of the hollowed-out portion on the substrate is within the orthographic projection of the first anode on the substrate; or, an orthographic projection of the hollowed-out portion on the substrate is within the orthographic projection of the second anode on the substrate; or, an orthographic projection of the hollowed-out portion on the substrate is within the orthographic projection of the third anode on the substrate.

According to one aspect of the present disclosure, there is provided a display panel, including a plurality of subpixels, and a plurality of pixel driving circuits for driving the plurality of subpixels respectively to emit light; each pixel driving circuit includes a drive transistor, a data writing transistor, and a first emission control transistor, wherein a first electrode of the data writing transistor is connected to a data line, a second electrode of the data writing transistor is connected to a first electrode of the drive transistor, a first electrode of the first emission control transistor is connected to a power supply line, and a second electrode of the first emission control transistor is connected to the first electrode of the drive transistor; and the display panel further includes:
a substrate; and
a conductive layer on a side of the substrate and including a plurality of power supply lines;
each subpixel includes an anode and a cathode opposite to each other, the anode is on a side of the conductive layer away from the substrate, and the cathode is on a side of the anode away from the substrate; the plurality of subpixels include a first subpixel, a second subpixel and a third subpixel having different emission colors; the anode of the first subpixel is a first anode, the anode of the second subpixel is a second anode, the anode of the third subpixel is a third anode, and the first anode and the third anode each have an area greater than the second anode; and an overlapping region is present between each of orthographic projections of the first anode, the second anode and the third anode on the substrate and an orthographic projection of a corresponding power supply line on the substrate;
one power supply line includes a plurality of conductive blocks distributed in the pixel column direction, wherein two adjacent conductive blocks are connected via a conductive line, and at least one of the first anode, the second anode or the third anode is not completely overlapped with the conductive block; and
for the conductive block and the anode not completely overlapped, an area of the conductive block exposed from the anode is greater than ⅕ an area of the anode.

Further, the orthographic projection of the second anode on the substrate is not completely overlapped with the orthographic projection of the conductive block on the substrate; and
the conductive layer includes a plurality of data lines, and an orthographic projection of a corresponding data line on the substrate is spaced apart from the orthographic projection of the second anode on the substrate; and an overlapping region is present between the orthographic projection of the corresponding data line on the substrate and each of the orthographic projections of the first anode and the third anode on the substrate.

Further, the second anode is not completely overlapped with the conductive block, and an area of a region of the orthographic projection of the conductive block on the substrate not overlapped with the orthographic projection of the second anode on the substrate is greater than ⅕ an area of the orthographic projection of the second anode on the substrate.

Further, a ratio of an area of the overlapping region between the orthographic projections of the first anode and the power supply line to an area of the first anode is less than a ratio of an area of the overlapping region between the orthographic projections of the second anode and the power supply line to an area of the second anode; and/or, a ratio of an area of the overlapping region between the orthographic projections of the third anode and the power supply line to an area of the third anode is less than a ratio of an area of the overlapping region between the orthographic projections of the second anode and the power supply line to the area of the second anode.

According to one aspect of the present disclosure, there is provided a display apparatus, including the display panel as described above.

### BRIEF DESCRIPTION OF DRAWINGS

FIG. 1 is a schematic diagram of a pixel driving circuit according to an implementation of the present disclosure.

FIG. 2 is a schematic diagram of a first active layer according to an implementation of the present disclosure.

FIG. 3 is a schematic partial view of the structure shown in FIG. 2.

FIG. 4 is a schematic diagram of a first gate electrode layer according to an implementation of the present disclosure.

FIG. 5 is a schematic diagram of a second gate electrode layer according to an implementation of the present disclosure.

FIG. 6 is a schematic diagram of a second active layer according to an implementation of the present disclosure.

FIG. 7 is a schematic diagram of a third gate electrode layer according to an implementation of the present disclosure.

FIG. 8 is a schematic diagram of a first source/drain electrode layer according to an implementation of the present disclosure.

FIGS. 9(a) and 9(b) are schematic diagrams of a conductive layer according to an implementation of the present disclosure.

FIG. 10 is a schematic diagram of an anode according to an implementation of the present disclosure.

FIGS. 11, 12 and 13 are schematic diagrams of a conductive layer and an anode according to an implementation of the present disclosure.

FIG. 14 is another schematic diagram of a first gate electrode layer according to an implementation of the present disclosure.

FIG. 15 is a schematic layout of a display panel according to an implementation of the present disclosure.

FIG. 16 is a schematic diagram of a display panel according to an implementation of the present disclosure.

List of reference characters: T1, first reset transistor; T2, compensation transistor; T3, drive transistor; T4, data writing transistor; T5, first emission control transistor; T6, second emission control transistor; T7, second reset transistor; C, energy storage capacitor; L0, subpixel; EM, emission control signal line; VDD, power supply line; Gate1, first scanning signal line; Data, data line; Gate2, second scanning signal line; Vini1, first initialization signal line; RST, reset signal line; Vini2, second initialization signal line; N1, first node; N2, second node; 1, first active layer; 101, first channel region; 102, second channel region; 103, third channel region; 104, fourth channel region; 105, fifth channel region; 2, first gate electrode layer; 201, first conductive part; 3, second gate electrode layer; 301, second conductive part; 4, second active layer; 401, sixth channel region; 402, seventh channel region; 5, third gate electrode layer; 501, first wire; 502, second wire; 6, first source/drain electrode layer; 601, first bridge; 602, second bridge; 603, third bridge; 604, first transition part; 605, second transition part; 7, conductive layer; 701, conductive block; 702, conductive line; 703, first line group; 704, second line group; 705, first anode transition part; 706, second anode transition part; 707, third anode transition part; 708, fourth anode transition part; 8, anode; 81, second electrode column; 82, first electrode column; 801, first anode; 802, second anode; 803, third anode; 804, hollowed-out portion; 9, substrate; 10, first gate insulation layer; 11, second gate insulation layer; 12, buffer layer; 13, third gate insulation layer; 14, interlayer insulation layer; 15, first planarization layer; and 16, second planarization layer.

### DETAIL DESCRIPTION OF EMBODIMENTS

The exemplary implementations will be explained in detail here, examples of which are illustrated in the accompanying drawings. The following description refers to the accompanying drawings in which the same numbers in different drawings represent the same or similar elements unless otherwise indicated. The implementations described in the following exemplary implementations do not represent all implementations consistent with the present disclosure. Rather, they are merely examples of apparatuses consistent with certain aspects of the present disclosure, as detailed in the appended claims.

The terminology used in the present disclosure is for the purpose of describing particular implementations only, and is not intended to limit the present disclosure. Unless otherwise defined, technical or scientific terms used in the present disclosure are intended to have general meanings as understood by those of ordinary skill in the art to which the present disclosure belongs. The words “first”, “second” and similar terms used in the description and the claims of the present disclosure do not denote any order, quantity, or importance, but are used merely for distinguishing different components from each other. Also, the use of the terms “a”, “an”, and the like does not denote a limitation of quantity, but rather denotes the presence of at least one. The term “a plurality of” or “several” means two or more. The word “comprise” or “include”, and the like, means that the element or item appearing in front of the word “comprise” or “include” includes the element or item listed after the word “comprise” or “include” and equivalents thereof, and does not exclude other elements or items. The terms “connected” or “coupled” and the like are not restricted to physical or mechanical connection, but may include electrical connection, either direct or indirect. As used in the specification of the present disclosure and the appended claims, the singular forms “a”, “an”, and “the” are intended to include the plural forms as well, unless the context clearly indicates otherwise. It should also be understood that the term “and/or” as used herein refers to and encompasses any and all possible combinations of one or more of the associated listed items.

In the existing art, subpixels of a display panel undergo three phases within one frame, i.e., charging, current ramp, and current-stabilized emission. The term “charging” refers to charging an anode of a subpixel. One subpixel may have different data voltages, and thus different charging currents, at different gray levels. For example, the charging current of the subpixel corresponding to a gray level L0 is less than the charging current of the subpixel corresponding to a gray level L32, and the data voltage of the subpixel corresponding to the gray level L0 is higher than the data voltage of the subpixel corresponding to the gray level L32. A difference between the data voltage of the subpixel corresponding to the gray level L0 and the data voltage of the subpixel corresponding to the gray level L32 is referred to as a data range. A larger data range can enable higher precision of Gamma adjustment, and further optimize the low grayscale image quality. However, due to a small data range, the low grayscale image quality is poor in the existing art.

An implementation of the present disclosure provides a display panel. The display panel may include a plurality of subpixels, and a plurality of pixel driving circuits for driving the plurality of subpixels to emit light in one-to-one correspondence. The plurality of subpixels include a plurality of first subpixels, a plurality of second subpixels, and a plurality of third subpixels. The first subpixels, the second subpixels and the third subpixels have different emission colors. For example, the first subpixels are red subpixels, the second subpixels are green subpixels, and the third subpixels are blue subpixels. One first subpixel, one second subpixel and one third subpixel may form one pixel. The plurality of subpixels may form a plurality of pixels. The plurality of pixels are arranged in an array, and form a plurality of pixel rows and a plurality of pixel columns. A pixel row direction is perpendicular to a pixel column direction.

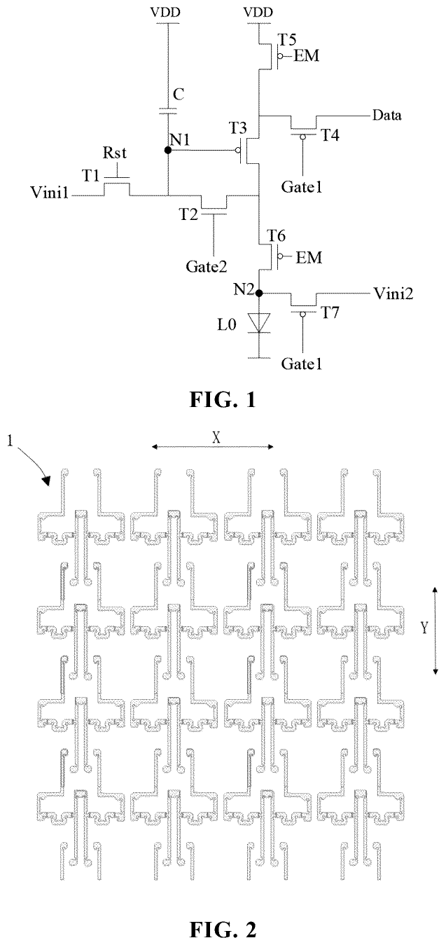

As shown in FIG. 1, each pixel driving circuit may include a first reset transistor T1, a second reset transistor T7, a drive transistor T3, a data writing transistor T4, a compensation transistor T2, a first emission control transistor T5, a second emission control transistor T6, and an energy storage capacitor C. In other words, each pixel driving circuit has a 7T1C structure. The first emission control transistor T5 has a gate connected to an emission control signal line EM, a first electrode connected to a power supply line VDD, and a second electrode connected to a first electrode of the drive transistor T3. The data writing transistor T4 has a gate connected to a first scanning signal line Gate1, a first electrode connected to a data line Data, and a second electrode connected to the first electrode of the drive transistor T3. The drive transistor T3 has a gate connected to a first node N1, and a second electrode connected to a first electrode of the compensation transistor T2. The compensation transistor T2 has a gate connected to a second scanning signal line Gate2, and a second electrode connected to the first node N1. The first reset transistor T1 has a first electrode connected to a first initialization signal line Vini1, a second electrode connected to the first node N1, and a gate connected to a reset signal line RST. The second emission control transistor T6 has a gate connected to the emission control signal line EM, a first electrode connected to the second electrode of the drive transistor T3, and a second electrode connected to a second node N2, and an anode 8 of a subpixel L0 is connected to the second node N2. The second reset transistor T7 has a first electrode connected to a second initialization signal line Vini2, a second electrode connected to the second node N2, and a gate connected to the first scanning signal line Gate1. The energy storage capacitor C may have a first plate connected to the first node N1, and a second plate connected to the power supply line VDD.

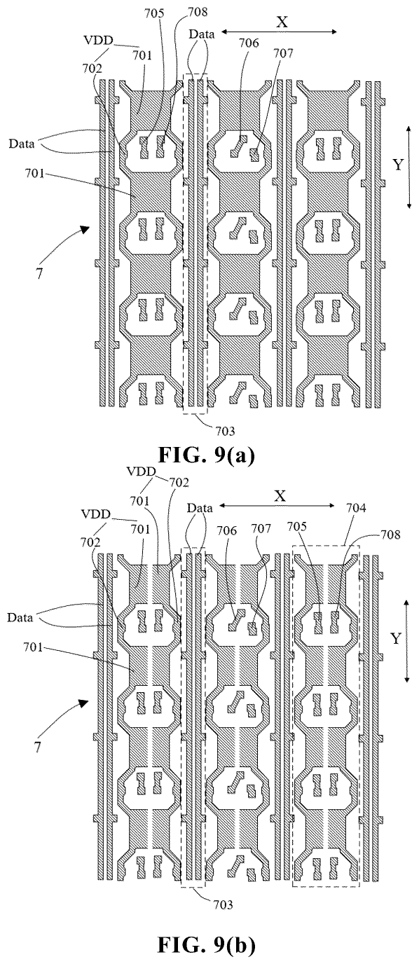

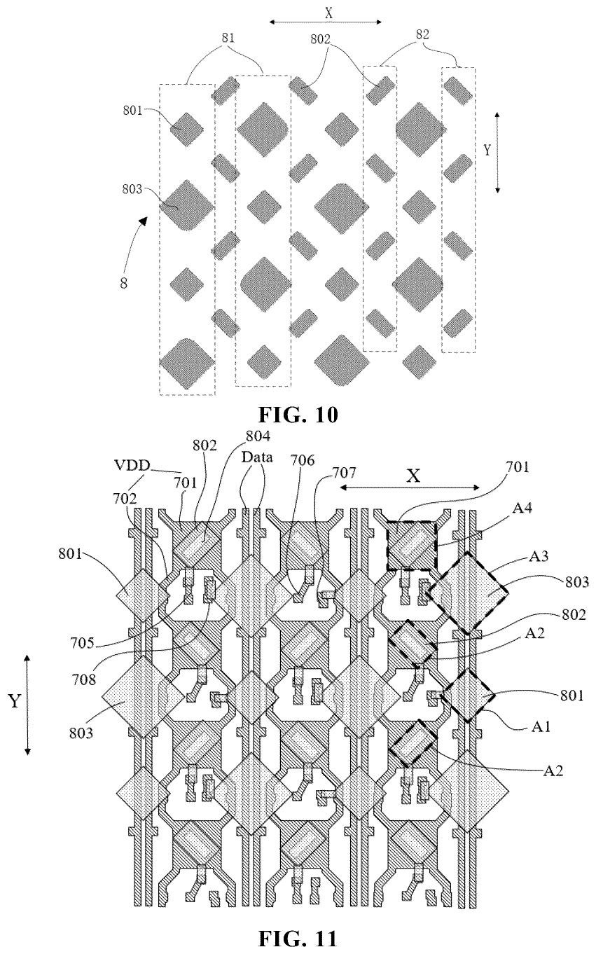

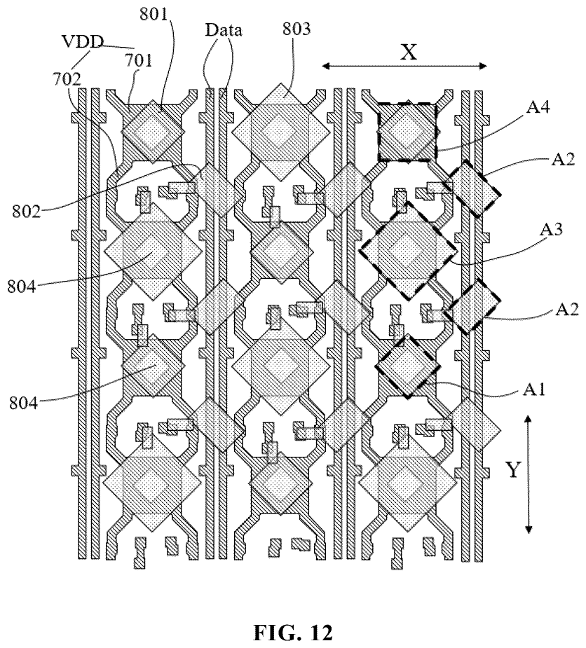

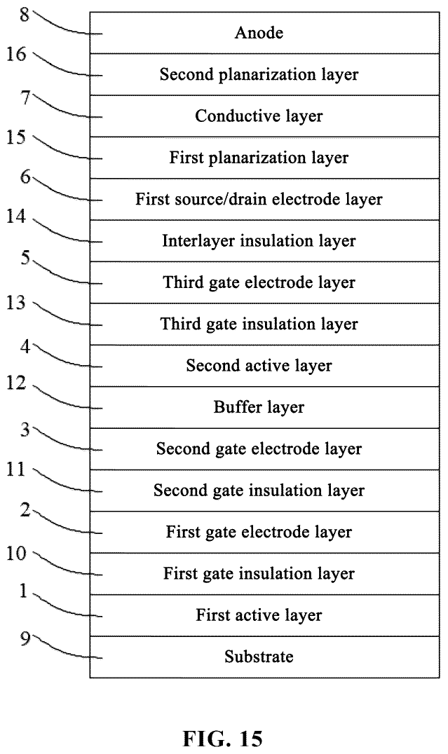

As shown in FIG. 15, the display panel of the present disclosure may include a substrate 9 and a conductive layer 7. The conductive layer 7 may be provided on a side of a substrate 9. As shown in FIG. 9(a), the conductive layer 7 may include a plurality of data lines Data and a plurality of power supply lines VDD as described above. Each subpixel L0 includes an anode 8 (FIG. 10) and a cathode opposite to each other. The anode 8 is on a side of the conductive layer 7 away from the substrate 9, and the cathode is on a side of the anode 8 away from the substrate 9. The anode 8 of a first subpixel L0 is a first anode 801, the anode 8 of a second subpixel L0 is a second anode 802, the anode 8 of a third subpixel L0 is a third anode 803, and the first anode 801 and the third anode 803 each have an area greater than the second anode 802. As shown in FIGS. 11 and 12, an overlapping region is present between each of orthographic projections of the first anode 801, the second anode 802 and the third anode 803 on the substrate 9 and an orthographic projection of a corresponding power supply line VDD on the substrate 9. An area of the overlapping region between at least one of the first anode 801, the second anode 802 or the third anode 803 and the power supply line VDD is less than ½ the area of the corresponding anode 8.

In the display panel according to the implementation of the present disclosure, the conductive layer 7 may be on a side of the substrate 9, and includes a plurality of data lines Data and a plurality of power supply lines VDD as described above, and an overlapping region is present between each of orthographic projections of the first anode 801, the second anode 802 and the third anode 803 on the substrate 9 and an orthographic projection of the corresponding power supply line VDD on the substrate 9, so as to improve the flatness of the anode 8, solve the problem of poor display caused by a difference in flatness of the anode 8, and further improve the display effect. Meanwhile, since the area of the overlapping region between at least one of the first anode 801, the second anode 802 or the third anode 803 and the power supply line VDD is less than ½ the area of the corresponding anode 8, so that the parasitic capacitance between the anode 8 and the power supply line VDD is reduced, the charging time of the anode 8 is shortened, and the current peak value during the current ramp phase is reduced. When the current peak value is reduced, the data voltage will also change. A change amplitude of the data voltage of the subpixel corresponding to the gray level L0 is greater than a change amplitude of the data voltage of the subpixel corresponding to the gray level L32, so that the difference in the data voltage (the difference between the data voltage of the gray level L0 and the data voltage of the gray level L32) is increased as a whole. That is, the data range is increased.

The display panel according to the implementations of the present disclosure is described in detail below:

The substrate 9 may be a rigid substrate. The rigid substrate may be a glass substrate or a polymethyl methacrylate (PMMA) substrate. Apparently, the substrate 9 may be a flexible substrate. The flexible substrate may be a polyethylene terephthalate (PET) substrate, a polyethylene naphthalate two formic acid glycol ester (PEN) substrate, or a polyimide (PI) substrate.

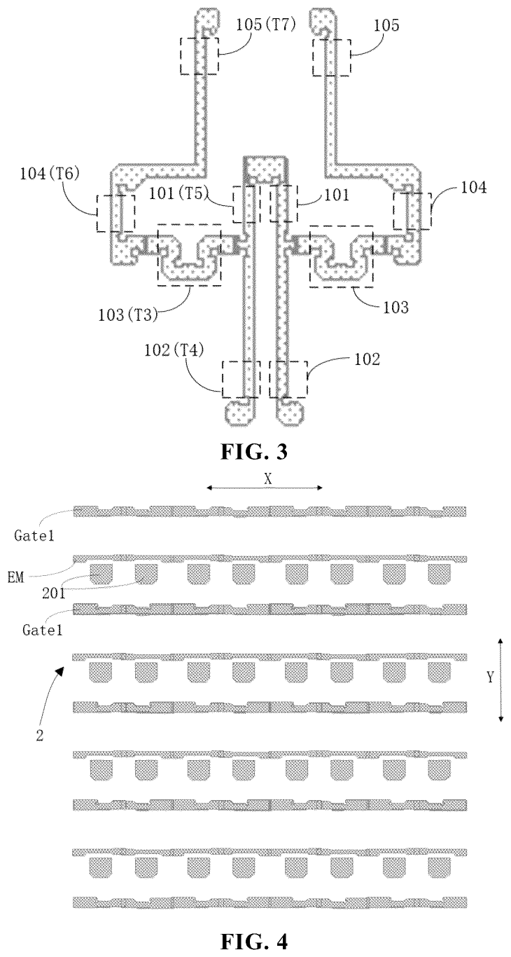

As shown in FIG. 15, the display panel may include a first active layer 1 (FIG. 2) on the substrate 9. Channel regions of the first emission control transistor T5, the data writing transistor T4, the drive transistor T3, the second emission control transistor T6 and the second reset transistor T7 are all located in the first active layer 1. As shown in FIG. 3, the first active layer 1 may include a first channel region 101, a second channel region 102, a third channel region 103, a fourth channel region 104, and a fifth channel region 105. The first channel region 101 is a channel region of the first emission control transistor T5. The second channel region 102 is a channel region of the data writing transistor T4. The third channel region 103 is a channel region of the drive transistor T3. The fourth channel region 104 is a channel region of the second emission control transistor T6. The fifth channel region 105 is a channel region of the second reset transistor T7. Source/drain regions of the first emission control transistor T5, the data writing transistor T4, the drive transistor T3, the second emission control transistor T6, and the second reset transistor T7 are also located in the first active layer 1.

As shown in FIG. 15, the display panel may further include a first gate insulation layer 10 and a first gate electrode layer 2 (FIG. 4). The first gate insulation layer 10 may be on a side of the first active layer 1 away from the substrate 9. The first gate electrode layer 2 may be on a side of the first gate insulation layer 10 away from the substrate 9. As shown in FIG. 4, the first Gate electrode layer 2 may include a first conductive part 201, the emission control signal line EM as described above, and the first scanning signal line Gate1 as described above. An orthographic projection of the first conductive part 201 on the substrate 9 may cover an orthographic projection of the channel region of the drive transistor T3 on the substrate 9, and the first conductive part 201 may form the gate electrode of the drive transistor T3 and the first plate of the energy storage capacitor C.

The emission control signal line EM may extend in the pixel row direction (X direction). An orthographic projection of the emission control signal line EM on the substrate 9 may cover orthographic projections of the channel regions of the first emission control transistor T5 and the second emission control transistor T6 on the substrate 9. One part of a structure of the emission control signal line EM is configured to form the gate of the first emission control transistor T5, while the other part is configured to form the gate of the second emission control transistor T6.

The first scanning signal line Gate1 may extend in the pixel row direction (X direction). An orthographic projection of the first scanning signal line Gate1 on the substrate 9 may cover orthographic projections of the channel regions of the data writing transistor T4 and the second reset transistor T7 on the substrate 9. One part of a structure of the first scanning signal line Gate1 is configured to form the gate of the data writing transistor T4, while the other part is configured to form the gate of the second reset transistor T7. It should be noted that for two adjacent first scanning signal lines Gate1 in the pixel column direction (Y direction), the orthographic projection of one first scanning signal line Gate1 on the substrate 9 may cover the orthographic projection of the channel region of the data writing transistor T4 on the substrate 9, while the orthographic projection of the other first scanning signal line Gate1 on the substrate 9 may cover the orthographic projection of the channel region of the second reset transistor T7 on the substrate 9.

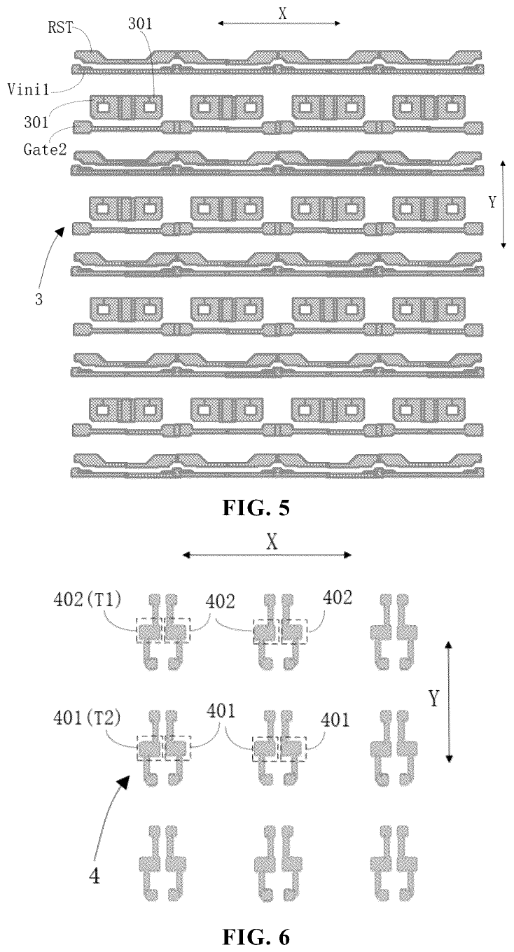

As shown in FIG. 15, the display panel may further include a second gate insulation layer 11 and a second gate electrode layer 3 (FIG. 5). The second gate insulation layer 11 may be on a side of the first gate electrode layer 2 away from the substrate 9. The second gate electrode layer 3 may be on a side of the second gate insulation layer 11 away from the substrate 9. The second gate electrode layer 3 may include a second conductive part 301, a reset signal line RST, a second scanning signal line Gate2, and a first initialization signal line Vini1. An orthographic projection of the second conductive part 301 on the substrate 9 is partially overlapped with the orthographic projection of the first conductive part 201 on the substrate 9. The second conductive part 301 may be configured to form the second plate of the energy storage capacitor C, and may be connected to the power supply line VDD in the conductive layer 7 through a via, so that the second plate of the energy storage capacitor C is connected to the power supply line VDD.

As shown in FIG. 15, the display panel may further include a buffer layer 12 and a second active layer 4 (FIG. 6). The buffer layer 12 may be on a side of the second gate electrode layer 3 away from the substrate 9. The second active layer 4 may be on a side of the buffer layer 12 away from the substrate 9. The channel regions of the compensation transistor T2 and the first reset transistor T1 are both located in the second active layer 4. Specifically, the second active layer 4 may include a sixth channel region 401 and a seventh channel region 402. The sixth channel region 401 is a channel region of the compensation transistor T2. The seventh channel region 402 is a channel region of the first reset transistor T1. Source/drain regions of the compensation transistor T2 and the first reset transistor T1 are also located in the second active layer 4.

The reset signal line RST (FIG. 5) may extend in the pixel row direction (X direction). An orthographic projection of the reset signal line RST on the substrate 9 may cover the orthographic projection of the channel region of the first reset transistor T1 on the substrate 9, and one part of a structure of the reset signal line RST is configured to form the gate, which is a bottom gate, of the first reset transistor T1.

The second scanning signal line Gate2 (FIG. 5) may extend in the pixel row direction (X direction). An orthographic projection of the second scanning signal line Gate2 on the substrate 9 may cover an orthographic projection of the channel region of the compensation transistor T2 on the substrate 9, and one part of a structure of the second scanning signal line Gate2 is configured to form the gate, which is a bottom gate, of the compensation transistor T2.

As shown in FIG. 15, the display panel may further include a third gate insulation layer 13 and a third gate electrode layer 5 (FIG. 7). The third gate insulation layer 13 may be on a side of the second active layer 4 away from the substrate 9. The third gate electrode layer 5 may be on a side of the third gate insulation layer 13 away from the substrate 9. The third gate electrode layer 5 may include a first wire 501 and a second wire 502. The first wire 501 may extend in the pixel row direction (X direction). An orthographic projection of the first wire 501 on the substrate 9 may cover the orthographic projection of the channel region of the first reset transistor T1 on the substrate 9, and one part of a structure of the first wire 501 is configured to form the gate, which is a top gate, of the first reset transistor T1. The first wire 501 may be electrically connected to the reset signal line RST. The second wire 502 may extend in the pixel row direction (X direction). An orthographic projection of the second wire 502 on the substrate 9 may cover an orthographic projection of the channel region of the compensation transistor T2 on the substrate 9, and one part of a structure of the second wire 502 is configured to form the gate, which is a top gate, of the compensation transistor T2. The second wire 502 may be electrically connected to the second scanning signal line Gate2.

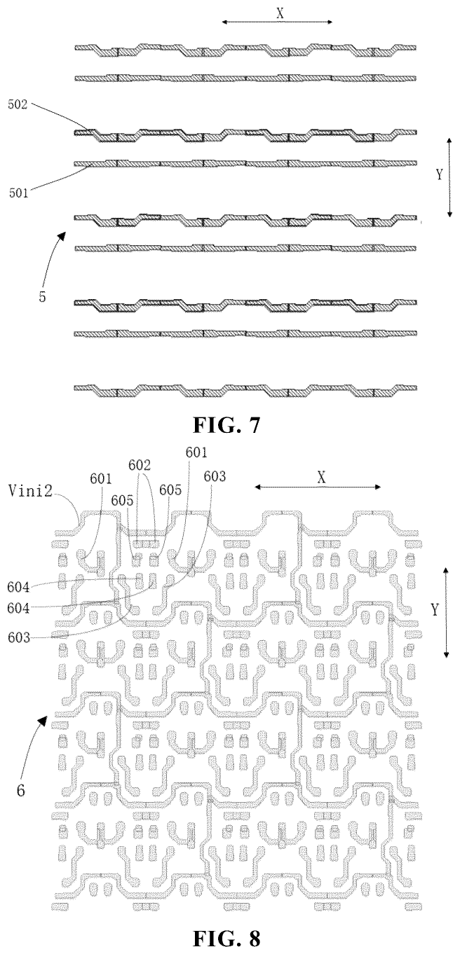

As shown in FIG. 15, the display panel may further include an interlayer insulation layer 14 and a first source/drain electrode layer 6 (FIG. 8). The interlayer insulation layer 14 may be on a side of the third gate electrode layer 5 away from the substrate 9. The first source/drain electrode layer 6 may be on a side of the interlayer insulation layer 14 away from the substrate 9. As shown in FIG. 8, the first source/drain electrode layer 6 may include a first bridge 601, a second bridge 602, a third bridge 603, a first transition part 604, a second transition part 605, and a second initialization signal line Vini2. The second initialization signal line Vini2 may be connected to one source/drain region of the second reset transistor T7 in the first active layer 1, thereby connecting the second initialization signal line Vini2 to the first electrode of the second reset transistor T7.

The first bridge 601 is connected to one source/drain region of the first emission control transistor T5 in the first active layer 1 through a via, and the first bridge 601 is configured to form a first electrode of the first emission control transistor T5. The first bridge 601 is connected to the second conductive part 301 (the second plate of the energy storage capacitor C) in the second gate electrode layer 3 through a via, and the first bridging portion 601 may be further connected to the power supply line VDD in the conductive layer 7 through a via, so that the first electrode of the first emission control transistor T5 is connected to the second plate of the energy storage capacitor C and the power supply line VDD, respectively.

The second bridge 602 is connected to one source/drain region of the first reset transistor T1 in the second active layer 4 through a via. The second bridge 602 is configured to form a first electrode of the first reset transistor T1, and the second bridge 602 may be further connected to the first initialization signal line Vini1 in the first gate electrode layer 2 through a via, so that the first electrode of the first reset transistor T1 is connected to the first initialization signal line Vini1.

The third bridge 603 is connected to the other source/drain region of the first reset transistor T1 in the second active layer 4 through a via, and the third bridge 603 is configured to form the second electrode of the first reset transistor T1. The third bridge 603 is further connected to a source/drain region of the compensation transistor T2 in the second active layer 4 through a via, and the third bridge 603 is configured to form the second electrode of the compensation transistor T2. The third bridge 603 is further connected to the first conductive part 201 (the first plate of the energy storage capacitor C) in the first gate electrode layer 2, so that the second electrode of the first reset transistor T1 and the second electrode of the compensation transistor T2 are connected to the first plate of the energy storage capacitor C.

The first transition part 604 is connected to one source/drain region of the data writing transistor T4 in the first active layer 1 through a via. The first transition part 604 is configured to form the first electrode of the data writing transistor T4, and the first transition part 604 may be further connected to the data line Data in the conductive layer 7 through a via, so that the first electrode of the data writing transistor T4 is connected to the data line Data.

The second emission control transistor T6 and the second reset transistor T7 share one source/drain region in the first active layer 1, and the source/drain region is connected to the second transition part 605, so that the second transition part 605 is configured to form a second electrode of the second emission control transistor T6, and to form the second electrode of the second reset transistor T7, and the second transition part 605 may be further connected to the anode 8 of the subpixel L0 through a via, so that the second electrode of the second emission control transistor T6 and the second electrode of the second reset transistor T7 are connected to the anode 8 of the subpixel L0.

As shown in FIGS. 9(a) and 15, the display panel may further include a first planarization layer 15 and a conductive layer 7. The first planarization layer 15 may be on a side of the first source/drain electrode layer 6 away from the substrate 9. The conductive layer 7 may be on a side of the first planarization layer 15 away from the substrate 9. The conductive layer 7 is a second source/drain electrode layer. The conductive layer 7 may include a data line Data. The data line Data may be connected to the first transition part 604 of the first source/drain electrode layer 6. The data line Data may extend in the pixel column direction (Y direction), and a plurality of data lines Data may be distributed in the pixel row direction (X direction). Two adjacent data lines Data may be mirror images of each other. Further, the plurality of data lines Data form a plurality of first line groups 703 arranged at intervals in the pixel row direction (X direction), and one first line group 703 includes at least two data lines Data. Taking one first line group 703 including two data lines Data as an example, the two data lines Data in the first line group 703 are mirror images of each other. For any two first line groups 703, the two data lines Data in one first line group 703 are mirror images of the two data lines Data in the other first line group 703. Further, in the pixel row direction (X direction), a distance between two adjacent first line groups 703 is greater than a distance between the two data lines Data in one first line group 703.

As shown in FIGS. 9(a) and 9(b), the conductive layer 7 may further include a power supply line VDD. The power supply line VDD may be connected to the first bridge 601 in the first source/drain electrode layer 6. The power supply line VDD may extend in the pixel column direction (Y direction), and a plurality of power supply lines VDD may be distributed in the pixel row direction (X direction). Two adjacent power supply lines VDD may be mirror images of each other. Further, as shown in FIG. 9(b), the plurality of the power supply lines VDD form a plurality of second line groups 704 arranged at intervals in the pixel row direction (X direction), and one second line group 704 includes two power supply lines VDD spaced apart. The two power supply lines VDD in the second line group 704 are mirror images of each other. For any two second line groups 704, the two power supply lines VDD in one second line group 704 are mirror images of the two power supply lines VDD in the other second line group 704. The plurality of second line groups 704 and the plurality of first line groups 703 are alternated in the pixel row direction (X direction).

In addition, one power supply line VDD includes a plurality of conductive blocks 701 distributed in the pixel column direction (Y direction). An orthographic projection of each conductive block 701 on the substrate 9 may have a rectangular shape, and a length of the conductive block 701 in the pixel row direction is less than a length of the conductive block 701 in the pixel column direction. Two adjacent conductive blocks 701 are connected via a conductive line 702. For two power supply lines VDD in any one of the second line groups 704, the plurality of conductive blocks 701 in one power supply line VDD are in one-to-one correspondence with, and spaced apart from, the plurality of conductive blocks 701 in the other power supply line VDD. The two corresponding conductive blocks 701 in FIG. 9(b) may be formed by digging grooves in the conductive blocks 701 in FIG. 9(a). In FIGS. 11 and 12, an area of the dotted box A4 is an area of an orthographic projection of the conductive block 701 on the substrate 9, which is also an area of the conductive block 701.

As shown in FIG. 15, the display panel may further include a second planarization layer 16 and a pixel defining layer. The second planarization layer 16 may be on a side of the conductive layer 7 away from the substrate 9. The pixel defining layer may be on a side of the second planarization layer 16 away from the substrate 9. The pixel defining layer is provided with a plurality of pixel openings.

The plurality of subpixels L0 are at the plurality of pixel openings in one-to-one correspondence. Each subpixel L0 may include an anode 8, a cathode, and a light-emitting layer. The anode 8 and the cathode are opposite to each other, and the light-emitting layer is located between the anode 8 and the cathode. The anode 8 is on a side of the second planarization layer 16 away from the substrate 9, the light-emitting layer is on a side of the anode 8 away from the substrate 9, and the cathode is on a side of the anode 8 away from the substrate 9.

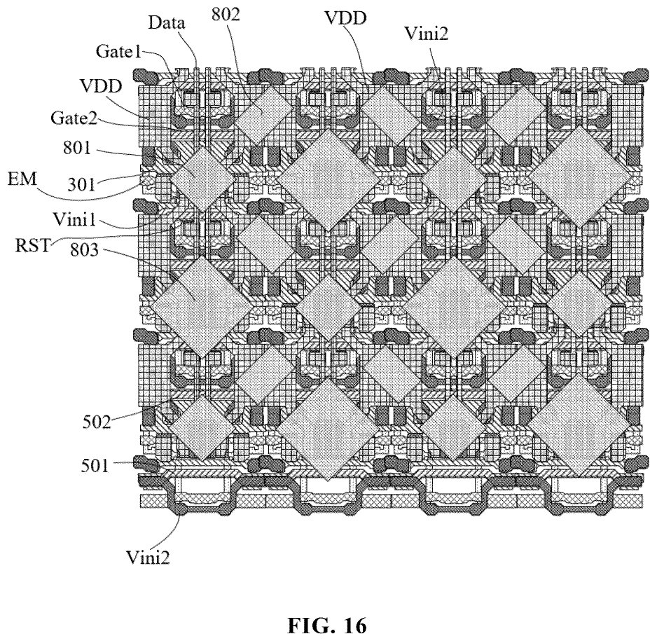

As shown in FIGS. 10 and 16, the anode 8 of a first subpixel L0 is taken as a first anode 801, the anode 8 of a second subpixel L0 is taken as a second anode 802, and the anode 8 of a third subpixel L0 is taken as a third anode 803. A plurality of second anodes 802 form a plurality of first electrode columns 82, and one first electrode column 82 includes a plurality of second anodes 802 distributed in the pixel column direction (Y direction). The plurality of first anodes 801 and the plurality of third anodes 803 form a plurality of second electrode columns 81, and one second electrode column 81 includes the first anodes 801 and the third anodes 803 alternated in the pixel column direction (Y direction). The first electrode columns 82 and the second electrode columns 81 are alternated in the pixel row direction (X direction). For a first electrode column 82 and a second electrode column 81 adjacent to each other, the anodes 8 in the first electrode column 82 are staggered with the anodes 8 in the second electrode column 81.

As shown in FIGS. 11 and 12, taking the anode 8 of a first subpixel L0 as a first anode 801, an overlapping region is present between an orthographic projection of the first anode 801 on the substrate 9 and an orthographic projection of the corresponding power supply line VDD on the substrate 9; taking the anode 8 of a second subpixel L0 as a second anode 802, an overlapping region is present between an orthographic projection of the second anode 802 on the substrate 9 and an orthographic projection of the corresponding power supply line VDD on the substrate 9; and taking the anode 8 of a third subpixel L0 as a third anode 803, an overlapping region is present between an orthographic projection of the third anode 803 on the substrate 9 and an orthographic projection of the corresponding power supply line VDD on the substrate 9. In FIGS. 11 and 12, an area of the dotted box A1 is an area of the orthographic projection of the first anode 801 on the substrate 9, which is also an area of the first anode 801; an area of the dotted box A2 is an area of the orthographic projection of the second anode 802 on the substrate 9, which is also an area of the second anode 802; and an area of the dotted box A3 is an area of the orthographic projection of the third anode 803 on the substrate 9, which is also an area of the third anode 803.

In one implementation, as shown in FIG. 11, an overlapping region is present between each of the orthographic projections of the first anode 801 and the third anode 803 on the substrate 9 and the orthographic projection of the corresponding data line Data on the substrate 9. Specifically, an overlapping region is present between each of the orthographic projections of the first anode 801 and the third anode 803, which are alternated in the pixel column direction (Y direction), i.e., alternated in the second electrode column 81, on the substrate 9 and the orthographic projection of the corresponding data line Data on the substrate 9. Further, an overlapping region is present between each of the orthographic projections of the first anode 801 and the third anode 803, which are alternated in the second electrode column 81, on the substrate 9 and each of the orthographic projections of the two data lines Data in the first line group 703 on the substrate 9. In addition, an overlapping region is present between the orthographic projection of the conductive line 702 on the substrate 9 and each of the orthographic projections of the first anode 801 and/or the third anode 803 on the substrate 9. Specifically, for two adjacent conductive lines 702 in the pixel column direction (Y direction), an overlapping region is present between orthographic projections of one conductive line 702 and the first anode 801 on the substrate 9, and an overlapping region is present between orthographic projections of the other conductive line 702 and the third anode 803 on the substrate 9. The orthographic projection of the second anode 802 on the substrate 9 is spaced apart from the orthographic projection of the data line Data on the substrate 9. The second anode 802 may be located between two adjacent data lines Data. Further, the second anode 802 may be located between two adjacent first line groups 703, while no second anode 802 is provided between the two data lines Data in the first line group 703. The orthographic projection of the conductive block 701 on the substrate 9 is spaced apart from the orthographic projection of the first anode 801 on the substrate 9, so that the parasitic capacitance between the first anode 801 and the power supply line VDD can be reduced, the charging time of the first anode 801 in the existing art can be further shortened, the data range can be increased, and the low grayscale image quality can be improved. Also, the orthographic projection of the conductive block 701 on the substrate 9 is spaced apart from the orthographic projection of the third anode 803 on the substrate 9, so that the parasitic capacitance between the third anode 803 and the power supply line VDD can be reduced, the charging time of the third anode 803 in the existing art can be further shortened, the data range can be increased, and the low grayscale image quality can be improved.

As shown in FIG. 11, for a second anode 802 between two adjacent first line groups 703, an overlapping region is present between an orthographic projection of the second anode 802 on the substrate 9 and an orthographic projection of the corresponding power supply line VDD on the substrate 9. Specifically, an overlapping region is present between the orthographic projection of the second anode 802 on the substrate 9 and an orthographic projection of the conductive block 701 of the corresponding power supply line VDD on the substrate 9, and an area of the overlapping region is less than an area of the orthographic projection of the conductive block 701 on the substrate 9. An area of a region of the orthographic projection of the conductive block 701 on the substrate 9 not overlapped with the orthographic projection of the second anode 802 on the substrate 9 is greater than ⅕ the area of the orthographic projection of the conductive block 701 on the substrate 9. The area of a region of the orthographic projection of the conductive block 701 on the substrate 9 not overlapped with the orthographic projection of the second anode 802 on the substrate 9 is greater than ⅕ the area of the orthographic projection of the second anode 802 on the substrate 9. The orthographic projection of the second anode 802 on the substrate 9 is spaced apart from the orthographic projection of the conductive line 702 of the power supply line VDD on the substrate 9. The orthographic projections of the plurality of conductive blocks 701 in one power supply line VDD on the substrate 9 are overlapped with the orthographic projections of the plurality of second anodes 802 in one first electrode column 82 on the substrate 9 in one-to-one correspondence. In addition, each conductive block 701 is provided with a hollowed-out portion 804, and an orthographic projection of the hollowed-out portion 804 on the substrate 9 is within the orthographic projection of the second anode 802 on the substrate 9. In this manner, the parasitic capacitance between the second anode 802 and the power supply line VDD can be further reduced. By forming the hollowed-out portion 804 in each conductive block 701, the present disclosure realizes uniform punching instead of excavating a large region separately, which can prevent overall sinking of the anode 8 above and obtain a relatively flat anode 8 as a whole, and, if there is any conformal micro pits, enable the anode 8 to form a lens structure that can further facilitate light emission.

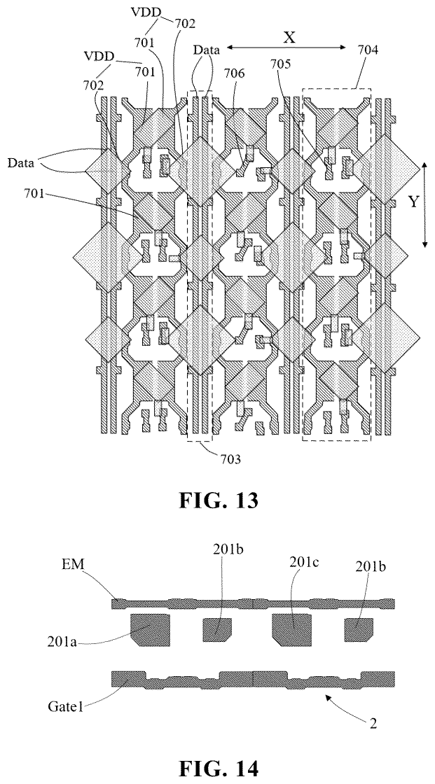

Further, as shown in FIG. 13, for two power supply lines VDD in one second line groups 704, the plurality of conductive blocks 701 in one power supply line VDD correspond to the plurality of conductive blocks 701 in the other power supply line VDD, respectively, and orthographic projections of one conductive block 701 in the one power supply line VDD and the corresponding conductive block 701 in the other power supply line VDD on the substrate 9 are overlapped with the orthographic projection of the same second anode 802 on the substrate 9.

In the present disclosure, a ratio of an area of the overlapping region between the orthographic projections of the first anode 801 and the power supply line VDD to the area of the orthographic projection of the first anode 801 on the substrate 9 is less thana ratio of an area of the overlapping region between the orthographic projections of the second anode 802 and the power supply line VDD to the area of the orthographic projection of the second anode 802 on the substrate 9; and a ratio of an area of the overlapping region between the orthographic projections of the third anode 803 and the power supply line VDD to the area of the orthographic projection of the third anode 803 on the substrate 9 is less than the ratio of the area of the overlapping region between the orthographic projections of the second anode 802 and the power supply line VDD to the area of the orthographic projection of the second anode 802 on the substrate 9.

In another implementation, as shown in FIGS. 9(a) and 11, at least one of the first anode 801, the second anode 802 or the third anode 803 in the present disclosure is not completely overlapped with the conductive block 701; and for the conductive block 701 and the anode 8 not completely overlapped, an area of the conductive block 701 exposed from the anode 8 is greater than ⅕ an area of the anode 8. In this manner, the parasitic capacitance between the anode 8 and the power supply line VDD can be reduced. Specifically, the second anode 802 is not completely overlapped with the conductive block 701, and an area of a region of the orthographic projection of the conductive block 701 on the substrate 9 not overlapped with the orthographic projection of the second anode 802 on the substrate 9 is greater than ⅕ the area of the orthographic projection of the second anode 802 on the substrate 9.

In addition, as shown in FIG. 11 and FIG. 14, taking the second subpixel L0 being a green subpixel as an example, due to the overlapping region between the orthographic projection of the second anode 802 on the substrate 9 and the orthographic projection of the conductive block 701 on the substrate 9, the energy storage capacitance C of the second subpixel L0 itself can be reduced (in FIG. 14, an area of the first conductive part 201b corresponding to the second anode 802 is less than an area of the first conductive part 201a corresponding to the first anode 801, and also less than an area of the first conductive part 201c corresponding to the third anode 803), so that the charging of the second subpixel L0 can be accelerated, and uniform RGB can be achieved.

In yet another implementation, as shown in FIG. 12, the conductive block 701 of the power supply line VDD is provided with a hollowed-out portion 804, an overlapping region is present between an orthographic projection of the first anode 801 on the substrate 9 and an orthographic projection of the conductive block 701 on the substrate 9, and an orthographic projection of the hollowed-out portion 804 on the substrate 9 is within the orthographic projection of the first anode 801 on the substrate 9. In this manner, the parasitic capacitance between the first anode 801 and the power supply line VDD can be reduced. An overlapping region is present between an orthographic projection of the third anode 803 on the substrate 9 and an orthographic projection of the conductive block 701 on the substrate 9, and an orthographic projection of the hollowed-out portion 804 on the substrate 9 is within the orthographic projection of the third anode 803 on the substrate 9. In this manner, the parasitic capacitance between the third anode 803 and the power supply line VDD can be reduced. The orthographic projections of the plurality of conductive blocks 701 in one power supply line VDD on the substrate 9 are overlapped with the orthographic projections of the plurality of anodes 8 in one second electrode column 81 on the substrate 9 in one-to-one correspondence. Specifically, the two adjacent conductive blocks 701 in one power supply line VDD, an overlapping region is present between orthographic projections of one conductive block 701 and the first anode 801 on the substrate 9, and an overlapping region is present between orthographic projections of the other conductive block 701 and the third anode 803 on the substrate 9. For two power supply lines VDD in one second line groups 704, the plurality of conductive blocks 701 in one power supply line VDD correspond to the plurality of conductive blocks 701 in the other power supply line VDD, respectively, and orthographic projections of one conductive block 701 in the one power supply line VDD and the corresponding conductive block 701 in the other power supply line VDD on the substrate 9 are overlapped with the orthographic projection of the same first anode 801 or third anode 803 on the substrate 9. Taking two conductive blocks 701 in one second line group 704 connected into a whole as an example, the hollowed-out portion 804 in one conductive block 701 forms through hole with the hollowed-out portion 804 in the other conductive block 701, and an orthographic projection of the through hole on the substrate 9 is within the orthographic projection of the first anode 801 or the third anode 803 on the substrate 9. The orthographic projection of the data line Data on the substrate 9 is spaced apart from the orthographic projections of the first anode 801 and the third anode 803 on the substrate 9, and an overlapping region is present between the orthographic projection of the data line Data on the substrate 9 and the orthographic projection of the second anode 802 on the substrate 9. The first anode 801 and the third anode 803 may be located between two adjacent data lines Data. Further, the first anode 801 and the third anode 803 may be located between two adjacent first line groups 703, while no first anode 801 or third anode 803 is provided between the two data lines Data in the first line group 703.

As shown in FIG. 12, taking the case where an overlapping region is present between the orthographic projection of the data line Data on the substrate 9 and the orthographic projection of the second anode 802 on the substrate 9 as an example, an overlapping region is present between each of the orthographic projections of the plurality of second anodes 802 in one first electrode column 82 on the substrate 9 and the orthographic projection of the same data line Data on the substrate 9. Further, an overlapping region is present between each of the orthographic projections of the plurality of second anodes 802 in the first electrode column 82 on the substrate 9 and the orthographic projections of the two data lines Data in the first line group 703 on the substrate 9. In addition, an overlapping region is present between the orthographic projection of the conductive line 702 on the substrate 9 and the orthographic projection of the second anode 802 on the substrate 9.

In addition, as shown in FIGS. 9(a) and 11, the conductive layer 7 further includes a first anode transition part 705 and a second anode transition part 706. In a pixel row direction, two adjacent second anodes 802 are connected to the first anode transition part 705 and the second anode transition part 706 in one-to-one correspondence. The plurality of pixel circuits include a first pixel circuit and a second pixel circuit which correspond to the two adjacent second anodes 802, respectively. The first pixel circuit is connected to a corresponding second anode 802 through the first anode transition part 705, and the second pixel circuit is connected to a corresponding second anode 802 through the second anode transition part 706. The first anode transition part 705 may be connected to the second electrode of the second emission control transistor T6 in the first pixel circuit, and the second anode transition part 706 may be connected to the second electrode of the second emission control transistor T6 in the second pixel circuit. An orthographic projection of the first anode transition part 705 on the substrate 9 is overlapped with an orthographic projection of the second electrode of the drive transistor T3 in the first pixel circuit on the substrate 9. An orthographic projection of the second electrode of the drive transistor T3 in a pixel circuit adjacent to the second pixel circuit on the substrate 9 is overlapped with an orthographic projection of the second anode transition part 706 on the substrate 9. In this manner, the electric field environment below the first anode transition part 705 is ensured to be consistent with the electric field environment below the second anode transition part 706. Here, the “pixel circuit adjacent to the second pixel circuit” refers to a pixel circuit adjacent to the second pixel circuit in the pixel row direction, and the “pixel circuit adjacent to the second pixel circuit” may be electrically connected to the first anode 801. In addition, the conductive layer 7 further includes a third anode transition part 707 and a fourth anode transition part 708. The first anode 801 is connected to the second electrode of the second emission control transistor T6 in the corresponding pixel circuit through the third anode transition part 707, and the third anode 803 is connected to the second electrode of the second emission control transistor T6 in the corresponding pixel circuit through the fourth anode transition part 708.

An implementation of the present disclosure further provides a display apparatus. The display apparatus may include the display panel according to any one of the above implementations. The display apparatus may be a mobile phone, a computer, a television and the like. The display panel and the display apparatus provided in the implementations of the present disclosure belong to the same inventive concept, and the description of relevant details and beneficial effects may be mutually referred to and will not be repeated.

Described above are merely preferred implementations of the present disclosure, and are not intended to limit the present disclosure in any form. Although the present disclosure has been disclosed in the above preferred implementations, the present disclosure is not limited thereto. Any person skilled in the art may, without departing from the scope of the technical solutions of the present disclosure, utilize the technical content disclosed above to make minor alterations or modifications as equivalent variations to equivalent implementations. However, any simple modifications, equivalent changes, and refinements made to the above implementations based on the technical essence of the present disclosure without departing from the content of the technical solutions of the present disclosure shall still fall within the scope of the technical solutions of the present disclosure.

1. A display panel, wherein the display panel comprises a plurality of subpixels, and a plurality of pixel driving circuits for driving the plurality of subpixels respectively to emit light; each pixel driving circuit comprises a drive transistor, a data writing transistor, and a first emission control transistor, wherein a first electrode of the data writing transistor is connected to a data line, a second electrode of the data writing transistor is connected to a first electrode of the drive transistor, a first electrode of the first emission control transistor is connected to a power supply line, and a second electrode of the first emission control transistor is connected to the first electrode of the drive transistor; and the display panel further comprises:
a substrate; and
a conductive layer on a side of the substrate and comprising a plurality of power supply lines; and
each subpixel comprises an anode and a cathode opposite to each other, the anode is on a side of the conductive layer away from the substrate, and the cathode is on a side of the anode away from the substrate; the plurality of subpixels comprise a first subpixel, a second subpixel and a third subpixel having different emission colors; the anode of the first subpixel is a first anode, the anode of the second subpixel is a second anode, the anode of the third subpixel is a third anode, and the first anode and the third anode each have an area greater than the second anode; and an overlapping region is present between each of orthographic projections of the first anode, the second anode and the third anode on the substrate and an orthographic projection of a corresponding power supply line on the substrate, and an area of the overlapping region between at least one of the first anode, the second anode or the third anode and the power supply line is less than ½ an area of a corresponding anode.

2. The display panel according to claim 1, wherein a ratio of an area of the overlapping region between the orthographic projections of the first anode and the power supply line to an area of the first anode is less than a ratio of an area of the overlapping region between the orthographic projections of the second anode and the power supply line to an area of the second anode; and/or, a ratio of an area of the overlapping region between the orthographic projections of the third anode and the power supply line to an area of the third anode is less than the ratio of the area of the overlapping region between the orthographic projections of the second anode and the power supply line to the area of the second anode.

3. The display panel according to claim 1, wherein the first subpixel is a red subpixel, the second subpixel is a green subpixel, and the third subpixel is a blue subpixel.

4. The display panel according to claim 1, wherein the conductive layer comprises a plurality of data lines, and an orthographic projection of a corresponding data line on the substrate is spaced apart from the orthographic projection of the second anode on the substrate; and an overlapping region is present between the orthographic projection of the corresponding data line on the substrate and each of the orthographic projections of the first anode and the third anode on the substrate.

5. The display panel according to claim 4, wherein the plurality of subpixels form a plurality of pixels, one pixel comprises multiple subpixels, and the plurality of pixels form a plurality of pixel rows and a plurality of pixel columns; each data line extends in a pixel column direction, and the plurality of data lines are arranged in a pixel row direction; and the second anode is located between two adjacent data lines; and
in the pixel column direction, at least some first anodes and at least some third anodes are alternated, and an overlapping region is present between each of orthographic projections of the alternated first anodes and third anodes on the substrate and the orthographic projection of the corresponding data line on the substrate.

6. The display panel according to claim 5, wherein the plurality of the data lines form a plurality of first line groups arranged at intervals in the pixel row direction, wherein one first line group comprises at least two data lines, and the second anode is located between two adjacent first line groups; and
an overlapping region is present between each of the orthographic projections of the alternated first anodes and third anodes on the substrate and each of orthographic projections of the at least two data lines in the first line group on the substrate.

7. The display panel according to claim 5, wherein one power supply line comprises a plurality of conductive blocks distributed in the pixel column direction, wherein two adjacent conductive blocks are connected via a conductive line;
an overlapping region is present between the orthographic projection of the second anode on the substrate and an orthographic projection of a corresponding conductive block on the substrate, and an area of the overlapping region is less than an area of the orthographic projection of the conductive block on the substrate; and
for two adjacent conductive lines in the pixel column direction, an overlapping region is present between an orthographic projection of one conductive line on the substrate and the orthographic projection of the first anode on the substrate, while an overlapping region is present between an orthographic projection of the other conductive line on the substrate and the orthographic projection of the third anode on the substrate.

8. The display panel according to claim 7, wherein an area of a region of the orthographic projection of the conductive block on the substrate not overlapped with the orthographic projection of the second anode on the substrate is greater than ⅕ the area of the orthographic projection of the conductive block on the substrate.

9. The display panel according to claim 7, wherein an area of a region of the orthographic projection of the conductive block on the substrate not overlapped with the orthographic projection of the second anode on the substrate is greater than ⅕ an area of the orthographic projection of the second anode on the substrate.

10. The display panel according to claim 7, wherein the plurality of the power supply lines form a plurality of second line groups arranged at intervals in the pixel row direction, wherein one second line group comprises two power supply lines spaced apart; the plurality of second line groups and the plurality of first line groups are alternated in the pixel row direction; and
for the two power supply lines in one second line group, the plurality of conductive blocks in one power supply line correspond to the plurality of conductive blocks in the other power supply line, respectively, and orthographic projections of one conductive block in the one power supply line and the corresponding conductive block in the other power supply line on the substrate are overlapped with the orthographic projection of a same second anode on the substrate.

11. The display panel according to claim 7, wherein each conductive block is provided with a hollowed-out portion, and an orthographic projection of the hollowed-out portion on the substrate is within the orthographic projection of the second anode on the substrate.

12. The display panel according to claim 1, wherein the plurality of subpixels form a plurality of pixels, one pixel comprises multiple subpixels, and the plurality of pixels form a plurality of pixel rows and a plurality of pixel columns; each power supply line extends in a pixel column direction, and the plurality of power supply lines are arranged in a pixel row direction; and one power supply line comprises a plurality of conductive blocks distributed in the pixel column direction, wherein two adjacent conductive blocks are connected via a conductive line, and each conductive block is provided with a hollowed-out portion; and
an overlapping region is present between the orthographic projection of the first anode on the substrate and an orthographic projection of a corresponding conductive block on the substrate, and an orthographic projection of the hollowed-out portion on the substrate is within the orthographic projection of the first anode on the substrate; and/or, an overlapping region is present between the orthographic projection of the third anode on the substrate and an orthographic projection of the corresponding conductive block on the substrate, and an orthographic projection of the hollowed-out portion on the substrate is within the orthographic projection of the third anode on the substrate.

13. The display panel according to claim 12, wherein the conductive layer comprises a plurality of data lines, and an orthographic projection of a corresponding data line on the substrate is spaced apart from the orthographic projections of the first anode and the third anode on the substrate; and an overlapping region is present between the orthographic projection of the corresponding data line on the substrate and the orthographic projection of the second anode on the substrate;
each data line extends in a pixel column direction, and the plurality of data lines are arranged in a pixel row direction; and the first anode and the third anode are located between two adjacent data lines;
a plurality of second anodes form a plurality of first electrode columns, and one first electrode column comprises a plurality of second anodes distributed in the pixel column direction; and an overlapping region is present between each of orthographic projections of a plurality of second anodes in the first electrode column on the substrate and an orthographic projection of a same data line on the substrate.

14. The display panel according to claim 1, wherein the conductive layer further comprises a first anode transition part and a second anode transition part; wherein in a pixel row direction, two adjacent second anodes are connected to the first anode transition part and the second anode transition part, respectively; and a plurality of pixel circuits comprise a first pixel circuit and a second pixel circuit which correspond to the two adjacent second anodes, respectively, wherein the first pixel circuit is connected to a corresponding second anode through the first anode transition part, and the second pixel circuit is connected to a corresponding second anode through the second anode transition part;
an orthographic projection of the first anode transition part on the substrate is overlapped with an orthographic projection of the second electrode of the drive transistor in the first pixel circuit on the substrate; and
an orthographic projection of the second electrode of the drive transistor in a pixel circuit adjacent to the second pixel circuit on the substrate is overlapped with an orthographic projection of the second anode transition part on the substrate.

15. The display panel according to claim 1, wherein each power supply line comprises a plurality of conductive blocks, two adjacent conductive blocks are connected via a conductive line, and each conductive block is provided with a hollowed-out portion; and
an orthographic projection of the hollowed-out portion on the substrate is within the orthographic projection of the first anode on the substrate; or, an orthographic projection of the hollowed-out portion on the substrate is within the orthographic projection of the second anode on the substrate; or, an orthographic projection of the hollowed-out portion on the substrate is within the orthographic projection of the third anode on the substrate.

16. A display panel, wherein the display panel comprises a plurality of subpixels, and a plurality of pixel driving circuits for driving the plurality of subpixels respectively to emit light; each pixel driving circuit comprises a drive transistor, a data writing transistor, and a first emission control transistor, wherein a first electrode of the data writing transistor is connected to a data line, a second electrode of the data writing transistor is connected to a first electrode of the drive transistor, a first electrode of the first emission control transistor is connected to a power supply line, and a second electrode of the first emission control transistor is connected to the first electrode of the drive transistor; and the display panel further comprises:
a substrate; and
a conductive layer on a side of the substrate and comprising a plurality of power supply lines; and
each subpixel comprises an anode and a cathode opposite to each other, the anode is on a side of the conductive layer away from the substrate, and the cathode is on a side of the anode away from the substrate; the plurality of subpixels comprise a first subpixel, a second subpixel and a third subpixel having different emission colors; the anode of the first subpixel is a first anode, the anode of the second subpixel is a second anode, the anode of the third subpixel is a third anode, and the first anode and the third anode each have an area greater than the second anode; and an overlapping region is present between each of orthographic projections of the first anode, the second anode and the third anode on the substrate and an orthographic projection of a corresponding power supply line on the substrate;
one power supply line comprises a plurality of conductive blocks distributed in the pixel column direction, wherein two adjacent conductive blocks are connected via a conductive line, and at least one of the first anode, the second anode or the third anode is not completely overlapped with the conductive block; and
for the conductive block and the anode not completely overlapped, an area of the conductive block exposed from the anode is greater than ⅕ an area of the anode.

17. The display panel according to claim 16, wherein the orthographic projection of the second anode on the substrate is not completely overlapped with the orthographic projection of the conductive block on the substrate; and
the conductive layer comprises a plurality of data lines, and an orthographic projection of a corresponding data line on the substrate is spaced apart from the orthographic projection of the second anode on the substrate; and an overlapping region is present between the orthographic projection of the corresponding data line on the substrate and each of the orthographic projections of the first anode and the third anode on the substrate.

18. The display panel according to claim 16, wherein the second anode is not completely overlapped with the conductive block, and an area of a region of the orthographic projection of the conductive block on the substrate not overlapped with the orthographic projection of the second anode on the substrate is greater than ⅕ an area of the orthographic projection of the second anode on the substrate.

19. The display panel according to claim 16, wherein a ratio of an area of the overlapping region between the orthographic projections of the first anode and the power supply line to an area of the first anode is less than a ratio of an area of the overlapping region between the orthographic projections of the second anode and the power supply line to an area of the second anode; and/or, a ratio of an area of the overlapping region between the orthographic projections of the third anode and the power supply line to an area of the third anode is less than a ratio of an area of the overlapping region between the orthographic projections of the second anode and the power supply line to the area of the second anode.

20. A display apparatus, wherein the display apparatus comprises the display panel according to claim 1.
